(19) United States
(12) Patent Application Publication
(10) Pub. No.: US 2026/0161859 A1
(43) Pub. Date: Jun. 11, 2026

(54) Simulation method of shield tunnel segment floating based on direct force immersed boundary method

(71) Applicant: Zhengzhou University, Zhengzhou (CN)

(72) Inventors: Xiaolong Li, Zhengzhou City (CN); Yanhui Zhong, Zhengzhou City (CN); Bei Zhang, Zhengzhou City (CN); Jinping Zhang, Zhengzhou City (CN); Pengchao Li, Zhengzhou City (CN); Ming Guo, Zhengzhou City (CN); Xiaofeng Liu, Zhengzhou City (CN); Chaoya Chen, Zhengzhou City (CN)

(21) Appl. No.: 19/180,092

(22) Filed: Apr. 15, 2025

(30) Foreign Application Priority Data
Oct. 10, 2024 (CN) 202411407022X

(51) Int. Cl. G06F 30/28

(52) U.S. Cl. CPC G06F 30/28

(57) ABSTRACT

A simulation method of shield tunnel segment floating includes steps of dividing a flow field into grids, obtaining numbers and center coordinates of control bodies, and setting flow field boundary conditions; initializing flow field parameters and calculation parameters; updating the area velocity of the control bodies in the current time step; discretizing the flow field control equation, and solving iteratively the flow field velocity and pressure; updating the velocity and position coordinates of the boundary discrete points; obtaining the velocity of the boundary discrete points, calculating the force generated by the boundary discrete points and discretizing the force to the whole flow field; and finally transmitting the velocity of the boundary discrete points, the force applied to each unit of the flow field, the force applied to the boundary discrete points and the updated slurry viscosity in the current time step to the next time step.

### CROSS REFERENCE OF RELATED APPLICATION

The present invention claims priority under 35 U.S.C. 119 (a-d) to CN 202411407022.X, filed Oct. 10, 2024.

### BACKGROUND OF THE PRESENT INVENTION

### Field of Invention

The present invention relates to the field of simulation technology, and more particularly to a simulation method of shield tunnel segment floating based on direct force immersed boundary method.

### Description of Related Arts

In the construction of shield tunneling, due to the existence of shield shell, a gap will be formed between the segment and the formation, in which the segment has been assembled and removed from the shield tail, so that the gap is the shield tail gap. If the shield tail gap is not filled in time, the formation instability and segment dislocation will be caused. The shield tail grouting is to fill the shield tail gap by injecting cement slurry into the gap. After grouting, the segment is surrounded by a circle of liquid slurry before the slurry is solidified. Due to the hollow inside of the segment and the small thickness relative to the outer diameter thereof, the gravity of the segment is less than the buoyancy force, which will cause the segment to float up. The problems such as segment misalignment, joint leakage and axis deviation caused by synchronous grouting segment floating in shield tunnels are becoming more and more obvious. If these problems are not paid attention to, they will seriously endanger the safety of construction.

At present, one simulation method of segment floating mainly simulates the slurry filling in the shield tail gap by the equivalent layer, and simulates the shield tail synchronous grouting process by changing the modulus of the equivalent layer. In essence, it simulates the fluid by reducing the modulus of the solid unit, which is unable to simulate the segment floating process well, and unable to study the pressure distribution of the slurry during the segment floating process, so it is unable to reveal the segment floating mechanism more realistically. Another simulation method in the prior art is to use CFD software to study the segment floating mechanism. However, due to the movement of the solid during the segment floating simulation process, the dynamic mesh technology is required. In the simulation process, the mesh needs to be re-divided continuously. Moreover, because the shield tail gap is relatively small, the mesh size needs to be divided very fine, which greatly increases the simulation cost and is prone to non-convergence. The patent CN 109684716B discloses a periodic interval optimization method for multi-layer deposition process of metal droplets, which is also unable to simulate the shield tunnel segment floating, and has the same drawbacks as the prior art.

Therefore, it is urgent for those skilled in art that how to provide a simulation method of shield tunnel segment floating, which is able to accurately and quickly simulate the shield tunnel segment floating and output the simulation result.

### SUMMARY OF THE PRESENT INVENTION

In view of the shortcomings of the prior art, the present invention aims to provide a simulation method of shield tunnel segment floating based on direct force immersed boundary method, so as to solve the problems of the simulation method of shield tunnel segment floating in the prior art, such as low accuracy and high cost.

To solve the above technical problems, the present invention adopts technical solutions as follows.

The present invention provides a simulation method of shield tunnel segment floating based on direct force immersed boundary method. The simulation method comprises steps of:
(step 10) dividing a flow field into grids based on an orthogonal control body of predetermined size, wherein the grids are taken as control bodies, numbering the control bodies, obtaining center coordinates of the control bodies, and setting conditions of a flow field boundary;
(step 20) contacting the flow field boundary through discrete slurry and segment, obtaining information of boundary discrete points, and initializing flow field parameters and calculation parameters;
(step 30) updating an area velocity of the control bodies in a current time step;
(step 40) discretizing flow field control equations by collocated grid finite volume method according to a force applied to each unit of the flow field in a previous time step, and solving iteratively flow field velocity and pressure;
(step 50) according to a force applied to the boundary discrete points in the previous time step, updating velocity and position coordinates of the boundary discrete points by segment motion control equations;
(step 60) obtaining the velocity of the boundary discrete points by one interpolation function, and calculating the force applied to the boundary discrete points by direct force method in the current time step;
(step 70) discretizing the force in (step 60) to the whole flow field with another interpolation function; and
(step 80) transmitting all of the velocity of the boundary discrete points, the force applied to the each unit of the flow field, the force applied to the boundary discrete points and an updated slurry viscosity in the current time step to a next time step until an external iteration reaches a specified time.

Furthermore, in (step 10), according to an outer diameter of shield tunnel segment and a width of shield tail gap, the size of the solution region of the flow field is set, that is, the predetermined size is set, the flow field is divided into multiple square grids in accordance with the predetermined size, the grids are defined as the control bodies, the control bodies are numbered, the center coordinates of the control bodies are obtained and stored, and the flow field boundary is set to be a wall boundary.

Furthermore, in (step 20), the flow field parameters comprise initial fluid velocity, initial fluid pressure, fluid density, fluid viscosity, time step and calculation time; the calculation parameters comprise thickness of the shield tunnel segment, inner diameter of the shield tunnel segment, outer diameter of the shield tunnel segment, segment density, number of the boundary discrete points, and coordinates of the boundary discrete points.

Furthermore, in (step 30), the area velocity is expressed by formulas of

$$\{ \begin{matrix}{u}_{f} ( i , j ) & = 0.5 * ( u ( i , j ) + u ( i - 1 , j ) ) \\ {v}_{f} ( i , j ) & = 0.5 * ( v ( i , j ) + v ( i , j - 1 ) )\end{matrix} ,$$

here, i and j represent indexes of the control bodies along x and y directions, respectively, μ_{f} represents wall velocity of the control bodies along the x direction, v_{f} represents wall velocity of the control bodies along the y direction, u represents velocity of the control bodies along the x direction, v represents velocity of the control bodies along the y direction, the wall velocity of the control bodies is 0 when a wall of the control bodies is the flow field boundary.

Furthermore, in (step 40), the flow field control equations are

$$\{ \begin{matrix}∇ \cdot {u}^{n + 1} & = 0 \\ ρ ( \frac{{u}^{n + 1} - {u}^{n}}{Δ t} ) + ∇ \cdot ( {u}^{n + 1} {u}^{n} ) & = - ∇ {p}^{n + 1} + μΔ {u}^{n + 1} + {f}^{n}\end{matrix} ,$$

here, uⁿ⁺¹ represents flow field velocity in n+1 time step, uⁿ represents flow field velocity in n time step, Δt represents time step, pⁿ⁺¹ represents flow field pressure in n+1 time step, ρ represents flow field density, μ represents flow field dynamic viscosity, ƒⁿ represents a force applied to a control body at x position in n time step.

Furthermore, in (step 50), the segment motion control equations are

$$\{ \begin{matrix}\frac{{dU}_{c}}{dt} & = - {\sum }_{K = 1}^{N} {F}_{K} Δ x Δ y + {Q}_{r} - Q \\ {I}_{c} \frac{d {ω}_{c}}{dt} & = - {\sum }_{K = 1}^{N} ( {X}_{K} - {X}_{c} ) {F}_{K} Δ x Δ y\end{matrix} ,$$

here, U_{c} represents velocity vector of segment centroid motion, Fₖ represents a force applied to a K^{th} boundary discrete point, Δx and Δy represent sizes of the control bodies along the x and y directions, respectively, N represents a total number of the boundary discrete points, Q represents segment buoyancy, Qᵣ represents segment buoyancy resistance, I_{c} represents segment rotational inertia, ω_{c} represents segment angular velocity, Xₖ represents position vector of the K^{th} boundary discrete point, and X_{c} represents position vector of segment center.

Furthermore, in (step 50), the velocity and the position coordinates of the boundary discrete points are calculated by formulas of

$$\{ \begin{matrix}{X}_{c}^{n + 1} & = {X}_{c}^{n} + {U}_{c}^{n + 1} Δ t \\ {θ}^{n + 1} & = {θ}^{n} + {ω}_{c}^{n + 1} Δ t \\ {X}^{n + 1} & = ( {X}^{n + 1} , {Y}^{n + 1} ) = ( \begin{matrix}cos {θ}^{n + 1} & - sin {θ}^{n + 1} \\ sin {θ}^{n + 1} & cos {θ}^{n + 1}\end{matrix} ) ( \begin{matrix}{x}^{n} \\ {y}^{n}\end{matrix} ) \\ {U}^{n + 1} ( X ) & = {X}_{c}^{n + 1} + {ω}_{c}^{n + 1} \times ( {X}^{n + 1} - {X}_{c}^{n + 1} )\end{matrix} ,$$

here,

$${X}_{c}^{n + 1}$$

represents position vector of segment center in n+1 time step,

$${X}_{c}^{n}$$

represents position vector of segment center in n time step,

$${U}_{c}^{n + 1}$$

represents velocity vector of segment centroid motion in n+1 time step,

$${ω}_{c}^{n + 1}$$

represents segment angular 8%+1 velocity in n+1 time step θⁿ, represents segment rotational angle in n time step, θⁿ⁺¹ represents segment rotational angle in n+1 time step, Xⁿ⁺¹ represents position vector of boundary discrete points in n+1 time step, Xⁿ⁺¹ represents position of boundary discrete points at X direction in n+1 time step, Yⁿ⁺¹ represents position of boundary discrete points at Y direction in n+1 time step, and Uⁿ⁺¹(X) represents velocity vector of the boundary discrete point at X position in n+1 time step.

Furthermore, in (step 60), the velocity of the boundary discrete points are calculated by a formula of

$$\tilde{U} ( X ) = \sum u ( x ) δ ( x - {X}^{n} ) Δ x Δ y ,$$

here, Ũ(X) represents intermediate velocity vector of a boundary discrete point at X position, u(x) represents velocity vector of a control body at X position, ^{x} represents position vector of the control bodies, Xⁿ represents position vector of boundary discrete points in n time step, and (x−Xⁿ) represents Dirac function.

Furthermore, in (step 60), the force applied to the boundary discrete points is calculated by direct force method through a formula of

$$F ( X , t ) = \frac{U ( X , t ) - \tilde{U} ( X , t )}{Δ t} ,$$

here, F(X:t) represents force applied to the boundary discrete point at X position and t time, U(X, t) represents velocity vector of the boundary discrete point at X position and t time which is obtained by the segment motion control equations, and Ũ(X,t) represents intermediate velocity vector of the boundary discrete point at X position and t time which is obtained by control body velocity interpolation.

Furthermore, in (step 70), the another interpolation function is, ƒⁿ⁺¹(x)=ΣFⁿ⁺¹δ(x−Xⁿ)ΔxΔy, here, ƒⁿ⁺¹(x) represents force applied to a control body at x position in n+1 time step.

Compared with the prior art, the simulation method of shield tunnel segment floating based on direct force immersed boundary method provided by the present invention has some beneficial effects as follows.

The simulation method of segment floating in the prior art is unable to simulate the process of segment floating well, unable to study the pressure distribution of slurry in the process of segment floating, and unable to reveal the mechanism of segment floating more realistically. In addition, it also greatly increases the simulation cost and is prone to non-convergence. However, The simulation method provided by the present invention has simple process, convenient operation and low cost. In the simulation method provided by the present invention, the flow field control equation is discretized by the collocated grid finite volume method, the flow field velocity and pressure are solved iteratively, the velocity and position coordinates of the boundary discrete points are updated by the segment motion control equation, the velocity of the boundary discrete points is obtained by one interpolation function, the force generated by the boundary discrete points is calculated by the direct force method and then discretized to the whole flow field by another interpolation function, and finally, all of the velocity of the boundary discrete points, the force applied to each unit of the flow field, the force applied to the boundary discrete points and the updated slurry viscosity in the current time step are transmitted to the next time step until the external iteration reaches the specified time, thus it is realized that the shield tunnel segment floating is quickly and accurately simulated and the simulation result is quickly and accurately outputted.

### BRIEF DESCRIPTION OF THE DRAWINGS

In order to more clearly explain technical solutions of the present invention, the drawings used in the description of embodiments of the present invention will be briefly introduced as below. Obviously, the drawings described below show some embodiments of the present invention, and for those skilled in the art, other relevant drawings are also able to be obtained according to these drawings without any creative work.

FIG. 1 is a flow chart of a simulation method of shield tunnel segment floating based on direct force immersed boundary method provided by the present invention.

FIG. 2 is a simulation result graph of segment floating obtained by the simulation method of shield tunnel segment floating based on direct force immersed boundary method provided by the present invention.

### DETAILED DESCRIPTION OF THE PREFERRED EMBODIMENT

In order to facilitate the understanding of the present invention, a more comprehensive description of the present invention is presented below with reference to the relevant drawings. A better embodiment of the present invention is given in the attached drawings. However, the present invention is able to be implemented in many different forms and is not limited to the embodiment described herein. On the contrary, this embodiment is for providing a more thorough and comprehensive understanding of the disclosure of the present invention.

Unless otherwise defined, all technical and scientific terms used herein have the same meaning as those commonly understood by technicians skilled in the technical field of the present invention. The terms used herein in the specification of the present invention are only for describing specific embodiments, and are not intended to limit the present invention.

The present invention provides a simulation method of shield tunnel segment floating based on direct force immersed boundary method, which is applied to the simulation process of shield tunnel segment floating. The simulation method comprises steps of:
(step 10) dividing a flow field into grids based on an orthogonal control body of predetermined size, wherein the grids are taken as control bodies, numbering the control bodies, obtaining center coordinates of the control bodies, and setting conditions of a flow field boundary;
(step 20) contacting the flow field boundary through discrete slurry and segment, obtaining information of boundary discrete points, and initializing flow field parameters and calculation parameters;
(step 30) updating an area velocity of the control bodies in a current time step;
(step 40) discretizing flow field control equations by collocated grid finite volume method according to a force applied to each unit of the flow field in a previous time step, and solving iteratively flow field velocity and pressure;
(step 50) according to a force applied to the boundary discrete points in the previous time step, updating velocity and position coordinates of the boundary discrete points by segment motion control equations;
(step 60) obtaining the velocity of the boundary discrete points by one interpolation function, and calculating the force applied to the boundary discrete points by direct force method in the current time step;
(step 70) discretizing the force in (step 60) to the whole flow field with another interpolation function; and (step 80) transmitting all of the velocity of the boundary discrete points, the force applied to the each unit of the flow field, the force applied to the boundary discrete points and an updated slurry viscosity in the current time step to a next time step until an external iteration reaches a specified time.

The simulation method provided by the present invention is able to quickly and accurately simulate the shield tunnel segment floating.

In order to enable those skilled in the art to better understand the technical solution of the present invention, the technical solution in the embodiment of the present invention is described clearly and completely in combination with the attached drawings.

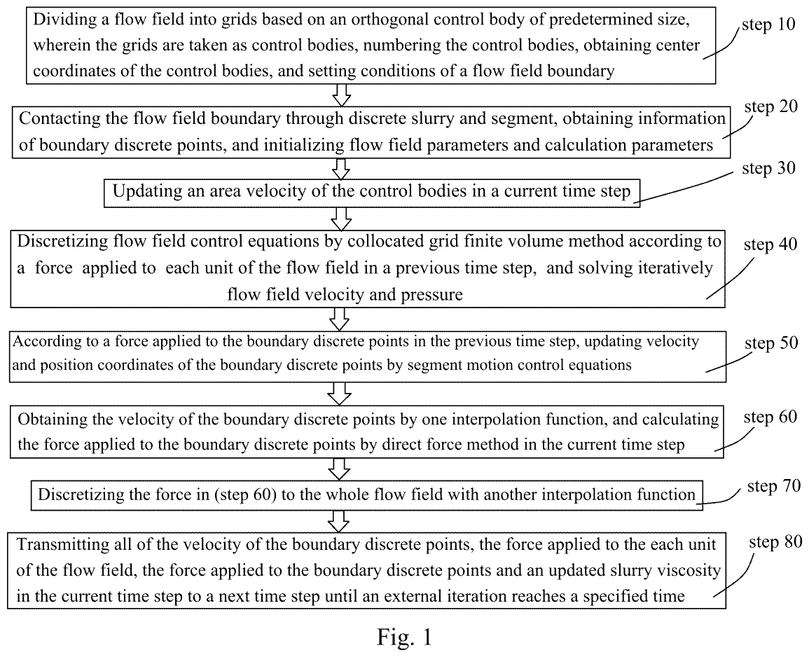

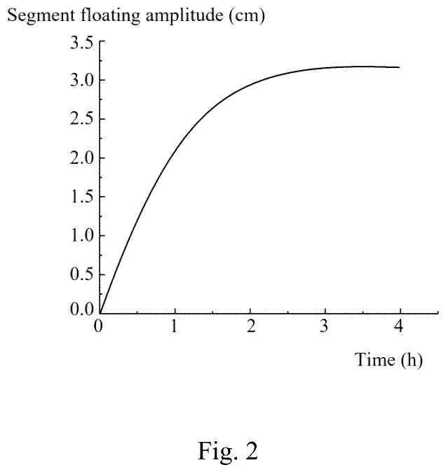

The present invention provides a simulation method of shield tunnel segment floating based on direct force immersed boundary method, which is applied to the simulation process of shield tunnel segment floating. Referring to FIGS. 1 and 2, according to the embodiment of the present invention, the simulation method comprises steps of:
(step 10) dividing a flow field into grids based on an orthogonal control body of predetermined size, wherein the grids are taken as control bodies, numbering the control bodies, obtaining center coordinates of the control bodies, and setting conditions of a flow field boundary, wherein:

according to an outer diameter of shield tunnel segment and a width of shield tail gap, the size of the solution region of the flow field is set, that is, the predetermined size is set, the flow field is divided into multiple square grids in accordance with the predetermined size, the grids are defined as the control bodies, the control bodies are numbered, the center coordinates of the control bodies are obtained and stored, and the flow field boundary is set to be a wall boundary;
(step 20) contacting the flow field boundary through discrete slurry and segment, obtaining information of boundary discrete points, and initializing flow field parameters and calculation parameters, wherein:

the flow field parameters comprise initial fluid velocity, initial fluid pressure, fluid density, fluid viscosity, time step and calculation time; the calculation parameters comprise thickness of the shield tunnel segment, inner diameter of the shield tunnel segment, outer diameter of the shield tunnel segment, segment density, number of the boundary discrete points, and coordinates of the boundary discrete points;
(step 30) updating an area velocity of the control bodies in a current time step, wherein the area velocity is expressed by formulas of

$$\{ \begin{matrix}{u}_{f} ( i , j ) & = 0.5 * ( u ( i , j ) + u ( i - 1 , j ) ) \\ {v}_{f} ( i , j ) & = 0.5 * ( v ( i , j ) + v ( i , j - 1 ) )\end{matrix} ,$$

here, i and j represent indexes of the control bodies along x and y directions, respectively, u_{f} represents wall velocity of the control bodies along the x direction, vs represents wall velocity of the control bodies along the y direction, μ represents velocity of the control bodies along the x direction, v represents velocity of the control bodies along the y direction, the wall velocity of the control bodies is 0 when a wall of the control bodies is the flow field boundary;
(step 40) discretizing flow field control equations by collocated grid finite volume method according to a force applied to each unit of the flow field in a previous time step, and solving iteratively flow field velocity and pressure, wherein the flow field control equations are

$$\{ \begin{matrix}∇ \cdot {u}^{n + 1} & = 0 \\ ρ ( \frac{{u}^{n + 1} - {u}^{n}}{Δ t} ) + ∇ \cdot ( {u}^{n + 1} {u}^{n} ) & = - ∇ {p}^{n + 1} + μΔ {u}^{n + 1} + {f}^{n}\end{matrix} ,$$

here, uⁿ⁺¹ represents flow field velocity in n+1 time step, uⁿ represents flow field velocity in n time step, Δt represents time step, pⁿ⁺¹ represents flow field pressure in n+1 time step, ρ represents flow field density, μ represents flow field dynamic viscosity, ƒⁿ represents a force applied to a control body at x position in n time step;
(step 50) according to a force applied to the boundary discrete points in the previous time step, updating velocity and position coordinates of the boundary discrete points by segment motion control equations, wherein:

the segment motion control equations are

$$\{ \begin{matrix}\frac{{dU}_{c}}{dt} & = - {\sum }_{K = 1}^{N} {F}_{K} Δ x Δ y + {Q}_{r} - Q \\ {I}_{c} \frac{d {ω}_{c}}{dt} & = - {\sum }_{K = 1}^{N} ( {X}_{K} - {X}_{c} ) {F}_{K} Δ x Δ y\end{matrix} ,$$

here, U_{c} represents velocity vector of segment centroid motion, Fₖ represents a force applied to a K^{th} boundary discrete point, Δx and Δy represent sizes of the control bodies along the x and y directions, respectively, N represents a total number of the boundary discrete points, Q represents segment buoyancy, Qᵣ represents segment buoyancy resistance, I_{c} represents segment rotational inertia, ω_{c} represents segment angular velocity, Xₖ represents position vector of the K^{th} boundary discrete point, and X_{c} represents position vector of segment center;

the velocity and the position coordinates of the boundary discrete points are calculated by formulas of

$$\{ \begin{matrix}{X}_{c}^{n + 1} & = {X}_{c}^{n} + {U}_{c}^{n + 1} Δ t \\ {θ}^{n + 1} & = {θ}^{n} + {ω}_{c}^{n + 1} Δ t \\ {X}^{n + 1} & = ( {X}^{n + 1} , {Y}^{n + 1} ) = ( \begin{matrix}cos {θ}^{n + 1} & - sin {θ}^{n + 1} \\ sin {θ}^{n + 1} & cos {θ}^{n + 1}\end{matrix} ) ( \begin{matrix}{x}^{n} \\ {y}^{n}\end{matrix} ) \\ {U}^{n + 1} ( X ) & = {X}_{c}^{n + 1} + {ω}_{c}^{n + 1} \times ( {X}^{n + 1} - {X}_{c}^{n + 1} )\end{matrix} ,$$

here,

$${X}_{c}^{n + 1}$$

represents position vector of segment center in n+1 time step,

$${X}_{c}^{n}$$

represents position vector of segment center in n time step,

$${X}_{c}^{n + 1}$$

represents velocity vector of segment centroid motion in n+1 time step,

$${ω}_{c}^{n + 1}$$

represents segment angular velocity in n+1 time step, θⁿ represents segment rotational angle in n time step, θⁿ⁺¹ represents segment rotational angle in n+1 time step, Xⁿ⁺¹ represents position vector of boundary discrete points in n+1 time step, Xⁿ⁺¹ represents position of boundary discrete points at X direction in n+1 time step, Yⁿ⁺¹ represents position of boundary discrete points at Y direction in n+1 time step, and Uⁿ⁺¹(X) represents velocity vector of the boundary discrete point at X position in n+1 time step;
(step 60) obtaining the velocity of the boundary discrete points by one interpolation function, and calculating the force applied to the boundary discrete points by direct force method in the current time step, wherein:

the velocity of the boundary discrete points are calculated by a formula of

$$\tilde{U} ( X ) = \sum u ( x ) δ ( x - {X}^{n} ) Δ x Δ y ,$$

here, Ũ(X) represents intermediate velocity vector of a boundary discrete point at X position, u(x) represents velocity vector of a control body at X position, x represents position vector of the control bodies, Xⁿ represents position vector of boundary discrete points in n time step, and (x−X^{x}) represents Dirac function which is

$${δ}_{h} ( x - {X}_{k}^{n} ) = {δ}_{h} ( r ) = \frac{1}{{h}^{2}} Φ ( \frac{{r}_{1}}{h} ) Φ ( \frac{{r}_{2}}{h} ) ,$$

here, φ(r) is a continuous function about r, the continuous function is

$$Φ ( r ) = \{ \begin{matrix}0 , & \vert r \vert \geq 2 \\ \frac{3 - 2 r + \sqrt{1 + 4 r - 4 {r}^{2}}}{8 h} , & \vert r \vert < 1 \\ \frac{5 - 2 r - \sqrt{- 7 + 12 r - 4 {r}^{2}}}{8 h} , & 1 \leq \vert r \vert < 2\end{matrix} ,$$

here, h is width of grids;

the force applied to the boundary discrete points is calculated by direct force method through a formula of

$$F ( X , t ) = \frac{U ( X , t ) - \tilde{U} ( X , t )}{Δ t} ,$$

here, F(X,t) represents force applied to the boundary discrete point at X position and t time, (X, t) represents velocity vector of the boundary discrete point at X position and t time which is obtained by the segment motion control equations, and Ũ(X,t) represents intermediate velocity vector of the boundary discrete point at X position and t time which is obtained by control body velocity interpolation;
(step 70) discretizing the force in (step 60) to the whole flow field with another interpolation function, wherein:

the another interpolation function is, ƒⁿ⁺¹(x)=ΣFⁿ⁺¹δ(x−Xⁿ)ΔxΔy, here, ƒⁿ⁺¹(x) represents force applied to a control body at x position in n+1 time step; and

(step 80) transmitting all of the velocity of the boundary discrete points, the force applied to the each unit of the flow field, the force applied to the boundary discrete points and an updated slurry viscosity in the current time step to a next time step until an external iteration reaches a specified time.

According to the present invention, the formula of slurry viscosity model is μ(t)=μ0e^{ξt}, here, μ(t) represents slurry viscosity at t time, μ₀ represents initial slurry viscosity, ξ represents parameters related to slurry properties.

### EMBODIMENT

Taking the shield tunnel segment of Zhengzhou Metro Line 12 as an example. Accordingly, the (step 10) is specifically as follows. The outer diameter of the shield tunnel segment is 6.2 m, the inner diameter thereof is 5.5 m, the thickness thereof is 0.35 m, the width of the shield tail gap is 0.2 m, the density of the shield tunnel segment is 2450 kg/m³, the control bodies are orthogonal control bodies with a length of side of 0.05 m. The control bodies are numbered, the center coordinates of the control bodies are generated and stored, and the flow field boundary is set as the wall boundary.

In (step 20), the flow field parameters comprise initial fluid velocity, initial fluid pressure, fluid density, fluid viscosity, time step and calculation time; the calculation parameters comprise thickness of the shield tunnel segment, inner diameter of the shield tunnel segment, outer diameter of the shield tunnel segment, segment density, number of the boundary discrete points, and coordinates of the boundary discrete points. In this embodiment, the initial fluid velocity is 0, the initial fluid pressure is one standard atmospheric pressure, the fluid density is 1830 kg/m³, the time step is 0.02 s, the calculation time is 10 h, the outer diameter of the shield tunnel segment is 6.2 m, the inner diameter of the shield tunnel segment is 5.5 m, the thickness of the shield tunnel segment is 0.35 m, the width of the shield tail gap is 0.2 m, the density of the shield tunnel segment is 2450 kg/m³, the number of the boundary discrete points is 389, and the initial coordinates of the boundary discrete points are calculated by formulas of

$$\{ \begin{matrix}{θ}_{i} = \frac{2 π}{389} * ( i - 1 ) , i = 1 , … , 389 \\ {X}_{i} = 0.5 * ( 6.2 + 2 * 0.2 ) + 0.5 * 6.2 * cos {θ}_{i} \\ {Y}_{i} = 0.5 * ( 6.2 + 2 * 0.2 ) + 0.5 * 6.2 * sin {θ}_{i}\end{matrix} .$$

In (step 30), the area velocity is expressed by formulas of

$$\{ \begin{matrix}{u}_{f} ( i , j ) = 0.5 * ( u ( i , j ) + u ( i - 1 , j ) ) \\ {v}_{f} ( i , j ) = 0.5 * ( v ( i , j ) + v ( i , j - 1 ) )\end{matrix} ,$$

here, i and j represent indexes of the control bodies along x and y directions, respectively, u_{f} represents wall velocity of the control bodies along the x direction, v_{f} represents wall velocity of the control bodies along the y direction, μ represents velocity of the control bodies along the x direction, v represents velocity of the control bodies along the y direction, the wall velocity of the control bodies is 0 when a wall of the control bodies is the flow field boundary.

In (step 40), the flow field control equations are

$$\{ \begin{matrix}∇ \cdot {u}^{n + 1} = 0 \\ ρ ( \frac{{u}^{n + 1} - {u}^{n}}{Δ t} ) + ∇ \cdot ( {u}^{n + 1} {u}^{n} ) = - ∇ {p}^{n + 1} + μΔ {u}^{n + 1} + {f}^{n}\end{matrix} ,$$

here, uⁿ⁺¹ represents flow field velocity in n+1 time step, uⁿ represents flow field velocity in n time step, Δt represents time step, pⁿ⁺¹ represents flow field pressure in n+1 time step, ρ represents flow field density, μ represents flow field dynamic viscosity, ƒⁿ represents a force applied to a control body at x position in n time step.

In (step 50), the segment motion control equations are

$$\{ \begin{matrix}\frac{{dU}_{c}}{dt} = - {\sum }_{K = 1}^{N} {F}_{K} Δ x Δ y + {Q}_{r} - Q \\ {I}_{c} \frac{d {ω}_{c}}{dt} = - {\sum }_{K = 1}^{N} ( {X}_{K} - {X}_{c} ) {F}_{K} Δ x Δ y\end{matrix} ,$$

here, U_{c} represents velocity vector of segment centroid motion, Fₖ represents a force applied to a K^{th} boundary discrete point, Δx and Δy represent sizes of the control bodies along the x and y directions, respectively, N represents a total number of the boundary discrete points, Q represents segment buoyancy, Qᵣ represents segment buoyancy resistance, I_{c} represents segment rotational inertia, ω_{c} represents segment angular velocity, Xₖ represents position vector of the K^{th} boundary discrete point, and X_{c} represents position vector of segment center.

Moreover, the velocity and the position coordinates of the boundary discrete points are calculated by formulas of

$$\{ \begin{matrix}{X}_{c}^{n + 1} = {X}_{c}^{n} + {U}_{c}^{n + 1} Δ t \\ {θ}^{n + 1} = {θ}^{n} + {ω}_{c}^{n + 1} Δ t \\ {X}^{n + 1} = ( {X}^{n + 1} , {Y}^{n + 1} ) = ( \begin{matrix}cos {θ}^{n + 1} & - sin {θ}^{n + 1} \\ sin {θ}^{n + 1} & cos {θ}^{n + 1}\end{matrix} ) ( \begin{matrix}{x}^{n} \\ {y}^{n}\end{matrix} ) \\ {U}^{n + 1} ( X ) = {X}_{c}^{n + 1} + {ω}_{c}^{n + 1} \times ( {X}^{n + 1} - {X}_{c}^{n + 1} )\end{matrix} ,$$

here,

$${X}_{c}^{n + 1}$$

represents position vector or segment center in n+1 time step,

$${X}_{c}^{n}$$

vector of segment centroid motion in n+1 time step,

$${U}_{c}^{n + 1}$$

represents velocity vector of segment centroid motion in n+1 time step,

$${ω}_{c}^{n + 1}$$

represents segment angular velocity in n+1 time step, θⁿ represents segment rotational angle in n time step, θⁿ⁺¹ represents segment rotational angle in n+1 time step, Xⁿ⁺¹ represents position vector of boundary discrete points in n+1 time step, Xⁿ⁺¹ represents position of boundary discrete points at X direction in n+1 time step, Yⁿ⁺¹ represents position of boundary discrete points at Y direction in n+1 time step, and Uⁿ⁺¹(X) represents velocity vector of the boundary discrete point at X position in n+1 time step.

In (step 60), the velocity of the boundary discrete points are calculated by a formula of

$$\tilde{U} ( X ) = \sum u ( x ) δ ( x - {X}^{n} ) Δ x Δ y ,$$

here, Ũ(X) represents intermediate velocity vector of a boundary discrete point at X position, u(x) represents velocity vector of a control body at X position, x represents position vector of the control bodies, Xⁿ represents position vector of boundary discrete points in n time step, and (x-Xⁿ) represents Dirac function which is

$${δ}_{h} ( x - {X}_{k}^{n} ) = {δ}_{h} ( r ) = \frac{1}{{h}^{2}} ϕ ( \frac{{r}_{1}}{h} ) ϕ ( \frac{{r}_{2}}{h} ) ,$$

here, φ(r) is a continuous function about r, the continuous function is

$$ϕ ( r ) = \{ \begin{matrix}0 , \vert r \vert \geq 2 \\ \frac{3 - 2 r + \sqrt{1 + 4 r - 4 {r}^{2}}}{8 h} , \vert r \vert < 1 \\ \frac{5 - 2 r - \sqrt{- 7 + 12 r - 4 {r}^{2}}}{8 h} , 1 \leq \vert r \vert < 2\end{matrix} ,$$

here, h is width of grids.

Moreover, the force applied to the boundary discrete points is calculated by direct force method through a formula of

$$F ( X , t ) = \frac{U ( X , t ) - \tilde{U} ( X , t )}{Δ t} ,$$

here, F(X,t) represents force applied to the boundary discrete point at X position and t time, U(x, t) represents velocity vector of the boundary discrete point at X position and t time which is obtained by the segment motion control equations, and Ũ(X, t) represents intermediate velocity vector of the boundary discrete point at X position and t time which is obtained by control body velocity interpolation.

In (step 70), the another interpolation function is ƒⁿ⁺¹(x)=ΣFⁿ⁺¹δ(x−Xⁿ)ΔxΔy, here, ƒⁿ⁺¹(x) represents force applied to a control body at x position in n+1 time step.

In the embodiment, the simulation method further comprises (step 8) transmitting all of the velocity of the boundary discrete points, the force applied to the each unit of the flow field, the force applied to the boundary discrete points and an updated slurry viscosity in the current time step to a next time step until an external iteration reaches a specified time.

According to the present invention, the formula of slurry viscosity model is, μ(t)=2*e^{0.01347t}, here, μ(t) represents slurry viscosity at t time, μ₀ represents initial slurry viscosity, ξ represents parameters related to slurry properties.

Through calculation, it is able to be seen from the simulation result of segment floating amount shown in FIG. 2 that, with the increase of slurry viscosity, the segment floating speed gradually decreases until the segment floating amount tends to be stable, which is consistent with the development process of segment floating during shield tunnel construction in actual engineering applications. Therefore, it is verified that the simulation method disclosed in this embodiment is reliable.

In the prior art, the simulation method of segment floating is unable to simulate the process of segment floating well, unable to study the pressure distribution of slurry in the process of segment floating, and unable to reveal the mechanism of segment floating more realistically. In addition, it also greatly increases the simulation cost and is prone to non-convergence. However, The simulation method provided by the present invention has simple process, convenient operation and low cost. In the simulation method provided by the present invention, the flow field control equation is discretized by the collocated grid finite volume method, the flow field velocity and pressure are solved iteratively, the velocity and position coordinates of the boundary discrete points are updated by the segment motion control equation, the velocity of the boundary discrete points is obtained by one interpolation function, the force generated by the boundary discrete points is calculated by the direct force method and then discretized to the whole flow field by another interpolation function, and finally, all of the velocity of the boundary discrete points, the force applied to each unit of the flow field, the force applied to the boundary discrete points and the updated slurry viscosity in the current time step are transmitted to the next time step until the external iteration reaches the specified time, thus it is realized that the shield tunnel segment floating is quickly and accurately simulated and the simulation result is quickly and accurately outputted.

What is claimed is:

1. A simulation method of shield tunnel segment floating based on direct force immersed boundary method, the simulation method comprising steps of:
(step 10) dividing a flow field into grids based on an orthogonal control body of predetermined size, numbering control bodies, obtaining center coordinates of the control bodies, and setting conditions of a flow field boundary;
(step 20) contacting the flow field boundary through discrete slurry and segment, obtaining information of boundary discrete points, and initializing flow field parameters and calculation parameters;
(step 30) updating an area velocity of control bodies of the flow field in a current time step;
(step 40) discretizing flow field control equations by collocated grid finite volume method according to a force applied to each unit of the flow field in a previous time step, and solving iteratively flow field velocity and pressure;
(step 50) according to a force applied to the boundary discrete points in the previous time step, updating velocity and position coordinates of the boundary discrete points by segment motion control equations;
(step 60) obtaining the velocity of the boundary discrete points by one interpolation function, and calculating the force applied to the boundary discrete points by direct force method in the current time step;
(step 70) discretizing the force in (step 60) to the whole flow field with another interpolation function; and
(step 80) transmitting the velocity of the boundary discrete points, the force applied to the each unit of the flow field, the force applied to the boundary discrete points and an updated slurry viscosity in the current time step to a next time step until an external iteration reaches a specified time.

2. The simulation method according to claim 1, wherein in (step 10), according to an outer diameter of shield tunnel segment and a width of shield tail gap, the predetermined size is set, the flow field is divided into multiple square grids in accordance with the predetermined size, the grids are defined as the control bodies, the control bodies are numbered, the center coordinates of the control bodies are obtained and stored, and the flow field boundary is set to be a wall boundary.

3. The simulation method according to claim 1, wherein in (step 20), the flow field parameters comprise initial fluid velocity, initial fluid pressure, fluid density, fluid viscosity, time step and calculation time; the calculation parameters comprise thickness of the shield tunnel segment, inner diameter of the shield tunnel segment, outer diameter of the shield tunnel segment, segment density, number of the boundary discrete points, and coordinates of the boundary discrete points.

4. The simulation method according to claim 1, wherein in (step 30), the area velocity is expressed by formulas of
$$\{ \begin{matrix}{u}_{f} ( i , j ) = 0.5 * ( u ( i , j ) + u ( i - 1 , j ) ) \\ {v}_{f} ( i , j ) = 0.5 * ( v ( i , j ) + v ( i , j - 1 ) )\end{matrix} ,$$
here, i and j represent indexes of the control bodies along x and y directions, respectively, u_{f} represents wall velocity of the control bodies along the x direction, v_{f} represents wall velocity of the control bodies along the y direction, u represents velocity of the control bodies along the x direction, v represents velocity of the control bodies along the y direction, the wall velocity of the control bodies is 0 when a wall of the control bodies is the flow field boundary.

5. The simulation method according to claim 1, wherein in (step 40), the flow field control equations are
$$\{ \begin{matrix}∇ \cdot {u}^{n + 1} = 0 \\ ρ ( \frac{{u}^{n + 1} - {u}^{n}}{Δ t} ) + ∇ \cdot ( {u}^{n + 1} {u}^{n} ) = - ∇ {p}^{n + 1} + μ Δ {u}^{n + 1} + {f}^{n}\end{matrix} ,$$
here, uⁿ⁺¹ represents flow field velocity in n+1 time step, uⁿ represents flow field velocity in n time step, Δt represents time step, pⁿ⁺¹ represents flow field pressure in n+1 time step, ρ represents flow field density, μ represents flow field dynamic viscosity, ƒⁿ represents a force applied to a control body at x position in n time step.

6. The simulation method according to claim 1, wherein in (step 50), the segment motion control equations are
$$\{ \begin{matrix}\frac{{dU}_{c}}{dt} = - {\sum }_{K = 1}^{N} {F}_{K} Δ x Δ y + {Q}_{r} - Q \\ {I}_{c} \frac{d {ω}_{c}}{dt} = - {\sum }_{K = 1}^{N} ( {X}_{K} - {X}_{c} ) {F}_{K} Δ x Δ y\end{matrix} ,$$
here, U_{c} represents velocity vector of segment centroid motion, Fₖ represents a force applied to a K^{th} boundary discrete point, Δx and Δy represent sizes of the control bodies along the x and y directions, respectively, N represents a total number of the boundary discrete points, Q represents segment buoyancy, Qᵣ represents segment buoyancy resistance, I_{c} represents segment rotational inertia, ω_{c} represents segment angular velocity, Xₖ represents position vector of the K^{th} boundary discrete point, and X_{c} represents position vector of segment center.

7. The simulation method according to claim 6, wherein in (step 50), the velocity and the position coordinates of the boundary discrete points are calculated by formulas of
$$\{ \begin{matrix}{X}_{c}^{n + 1} = {X}_{c}^{n} + {U}_{c}^{n + 1} Δ t \\ {θ}^{n + 1} = {θ}^{n} + {ω}_{c}^{n + 1} Δ t \\ {X}^{n + 1} = ( {X}^{n + 1} , {Y}^{n + 1} ) = ( \begin{matrix}cos {θ}^{n + 1} & - sin {θ}^{n + 1} \\ sin {θ}^{n + 1} & cos {θ}^{n + 1}\end{matrix} ) ( \begin{matrix}{x}^{n} \\ {y}^{n}\end{matrix} ) \\ {U}^{n + 1} ( X ) = {X}_{c}^{n + 1} + {ω}_{c}^{n + 1} \times ( {X}^{n + 1} - {X}_{c}^{n + 1} )\end{matrix} ,$$
here,
$${X}_{c}^{n + 1}$$
represents position vector of segment center in n+1 time step,
$${X}_{c}^{n}$$
represents position vector of segment center in n time step,
$${U}_{c}^{n + 1}$$
represents velocity vector of segment centroid motion in n+1 time step,
$${ω}_{c}^{n + 1}$$
represents segment angular velocity in n+1 time step, θⁿ represents segment rotational angle in n time step, θⁿ⁺¹ represents segment rotational angle in n+1 time step, Xⁿ⁺¹ represents position vector of boundary discrete points in n+1 time step, Xⁿ⁺¹ represents position of boundary discrete points at X direction in n+1 time step, Yⁿ⁺¹ represents position of boundary discrete points at Y direction in n+1 time step, and Uⁿ⁺¹(X) represents velocity vector of the boundary discrete point at X position in n+1 time step.

8. The simulation method according to claim 1, wherein in (step 60), the boundary discrete points are calculated by a formula of
$$\tilde{U} ( X ) = \sum u ( x ) δ ( x - {X}^{n} ) Δ x Δ y ,$$
here, Ũ(X) represents intermediate velocity vector of a boundary discrete point at X position, u(x) represents velocity vector of a control body at X position, x represents position vector of the control bodies, Xⁿ represents position vector of boundary discrete points in n time step, and (x−Xⁿ) represents Dirac function.

9. The simulation method according to claim 8, wherein in (step 60), the force applied to the boundary discrete points is calculated by direct force method through a formula of
$$F ( X , t ) = \frac{U ( X , t ) - \tilde{U} ( X , t )}{Δ t}$$
here, F(X,t) represents force applied to the boundary discrete point at X position and t time, U(X, t) represents velocity vector of the boundary discrete point at X position and t time which is obtained by the segment motion control equations, and Ũ(X,t) represents intermediate velocity vector of the boundary discrete point at X position and t time which is obtained by control body velocity interpolation.

10. The simulation method according to claim 1, wherein in (step 70), the another interpolation function is ƒⁿ⁺¹(x)=ΣFⁿ⁺¹δ(x−Xⁿ)ΔxΔy, here, ƒⁿ⁺¹(x) represents force applied to a control body at x position in n+1 time step.
